(19) United States
(12) Patent Application Publication
(10) Pub. No.: US 2013/0319503 A1
(43) Pub. Date: Dec. 5, 2013

(54) SOLAR RECEIVER

(71) Applicants: Yazdan Mantilla, San Jose, CA (US); Beomhee Lee, Sant Clara, CA (US)

(72) Inventors: Yazdan Mantilla, San Jose, CA (US); Beomhee Lee, Sant Clara, CA (US)

(73) Assignee: PHOTONRGY, San Jose, CA (US)

(21) Appl. No.: 13/487,817

(22) Filed: Jun. 4, 2012

(51) Int. Cl. H01L 31/052

(52) U.S. Cl. 136/246

(57) ABSTRACT

A concentrated photovoltaic receiver is exposed to concentrated sunlight so that the concentrated photovoltaic receiver generates electricity. The concentrated photovoltaic receiver is mounted on a solar receiver. The fluid is passed through a narrowed region within the solar receiver. The narrowed region is located adjacent to the concentrated photovoltaic receiver so that thermal energy is transferred from the concentrated sunlight to the fluid as the fluid passes through the narrowed region.

### BACKGROUND

Concentrated solar power systems concentrate sunlight before converting the light into useful power. The sunlight is concentrated typically using parabolic dish reflectors or lenses that are automatically positioned based on the location of the sun. At the location of concentration, power conversion units collect the power thermally or via photovoltaic converters.

### BRIEF DESCRIPTION OF DRAWINGS

FIG. 1 shows a partially disassembled solar receiver that heats fluid and generates electricity in accordance with an implementation.

FIG. 2 shows the concentrating heat and electricity system shown in FIG. 1, fully assembled in accordance with an implementation.

FIG. 3 shows a cross-sectional view of the concentrating heat and electricity system shown in FIG. 1, fully assembled, in accordance with an implementation.

FIG. 4 shows a receiver module of the concentrating heat and electricity system shown in FIG. 1, in accordance with an implementation.

FIG. 5 shows cross-sectional view illustrating concentration of light toward a solar receiver of the receiver module shown in FIG. 4, in accordance with an implementation.

FIG. 6 shows a cross-sectional view illustrating concentration of light toward a solar receiver of the receiver module shown in FIG. 4, in accordance with another implementation.

FIG. 7 shows a solar receiver in accordance with an implementation.

FIG. 8 is a cross-sectional view of the solar receiver shown in FIG. 7, in accordance with an implementation.

FIG. 9 is a top view of the solar receiver shown in FIG. 7, with a concentrated photovoltaic (CPV) receiver removed, in accordance with an implementation.

FIG. 10 shows a solar receiver in accordance with another implementation.

FIG. 11 is a cross-sectional view of the solar receiver shown in FIG. 10, in accordance with an implementation.

### DETAILED DESCRIPTION

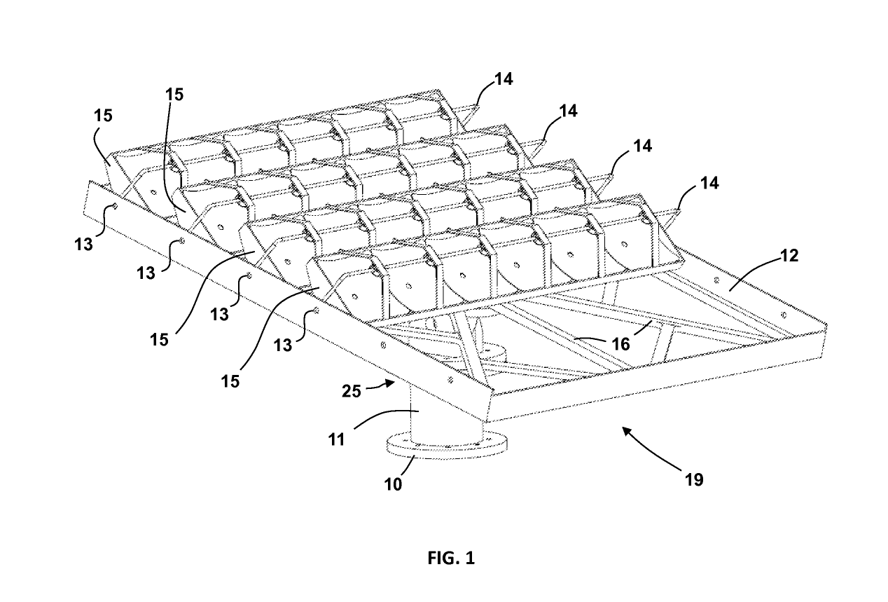

FIG. 1 shows a partially disassembled concentrating heat and electricity system 19 that heats fluid and generates electricity. Concentrating heat and electricity system 19 includes receiver modules 15 arranged within a frame 12. Frame 12 includes support structures 16 to support the weight of receiver modules 15. Each of receiver modules 15 can pivots on an axis of rotation 13.

A connector 10 is used to affix solar receiver 19 to a surface that is or can be exposed to sunlight. For example, the surface can be a rooftop of a building, a surface area on the ground, or a surface of a mobile device that can be moved into sunlight. A support pillar 11 is part of a base support structure that attaches connector 10 to frame 12. Frame 12 can be rotated an axis of support pillar 11 allowing positioning of the receiver modules 15 with respect to the sun to be optimized for capture of solar energy. Fluid flowing through transport pipes 14 is heated by receiver modules 15.

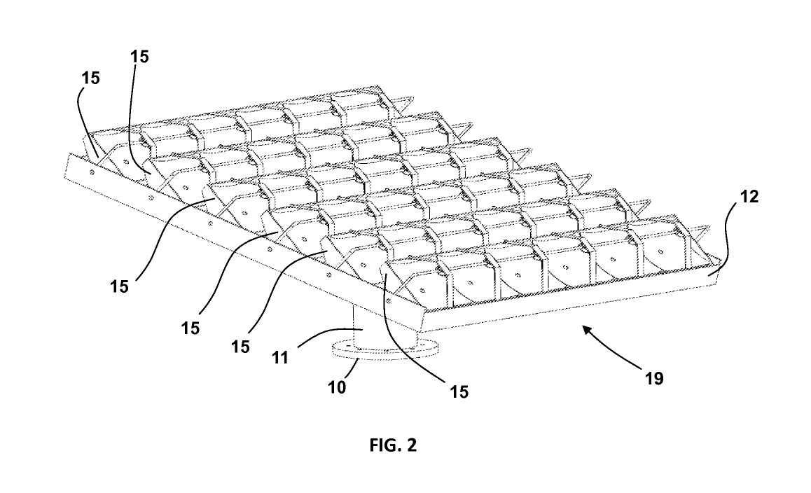

FIG. 2 shows concentrating heat and electricity system 19 fully assembled with receiver modules 15. While FIG. 2 shows six receiver modules 15, the number and shape of receiver modules 15 can vary depending on application, desired amount of energy production and so on. Multiple concentrating heat and electricity systems can be mounted together to increase the production of thermal and electrical energy.

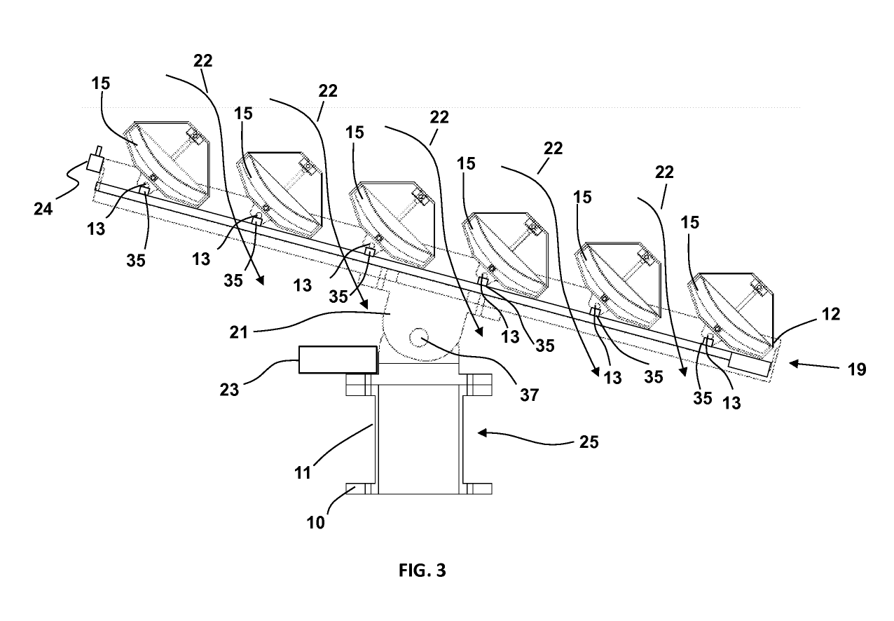

FIG. 3 shows a cross-sectional view of concentrating heat and electricity system 19. A space 22 between each receiver module 15 is provided to allow wind to flow between receiver modules 15. This reduces load on base support structure 25.

A solar tracker 24 monitors a position of the sun to allow for optimal positioning of receiver module 15 for efficient collection of solar energy. Module linkage 35 links each receiver module 15 to frame 12 and allows each receiver module 15 to pivot around its axis of rotation 13. Elevation motion motor 36 and associated motion mechanisms controls rotation of each receiver module 15 around its axis of rotation 13.

An assembly 21 is used to control rotation of frame 12 around an axis of rotation 37. A motion motor and mechanism 23 controls rotation of frame 12 around an axis of support pillar 11.

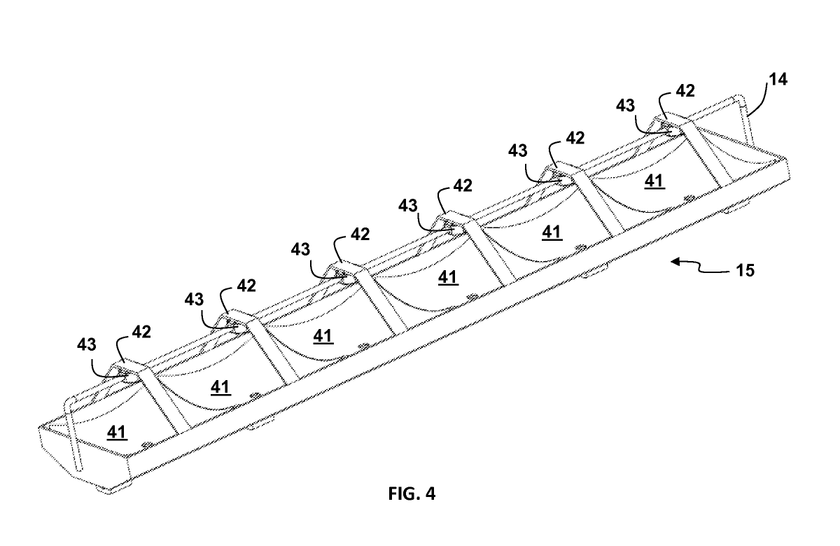

FIG. 4 shows additional detail of receiver module 15. Each receiver module includes reflectors 41 that collect and reflect sunlight towards solar receivers 43. Each of reflectors 41 provides concentrated light to one of solar receivers 43. Support structures 42 hold solar receivers 43 in position to receive the concentrated light.

Solar receivers 43 utilize energy in the concentrated light to heat fluid from transport pipes 14 through solar receivers 43. Solar receivers 43 also convert the concentrated light to electricity via a concentrated photovoltaic (CPV) receiver included as part of each solar receiver 43.

FIG. 5 is a cross-sectional view illustrating concentration of light 51 by reflector 41 towards solar receiver 43. For example, reflector 41 is a parabolic reflector composed of metal, plastic or other material with a highly reflective top surface.

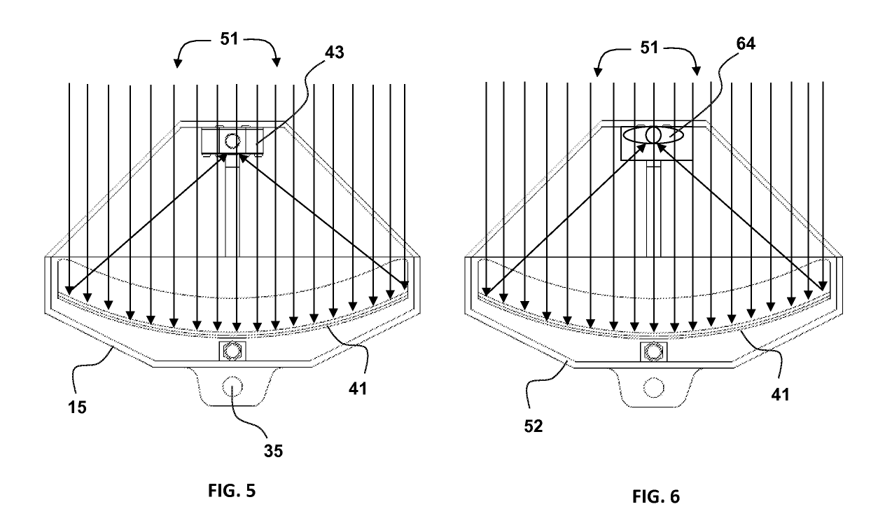

FIG. 6 is a cross-sectional view illustrating concentration of light 51 by reflector 41 towards solar receiver 64. Solar receiver 64 is an alternative implementation of solar receiver 43 shown in FIG. 5.

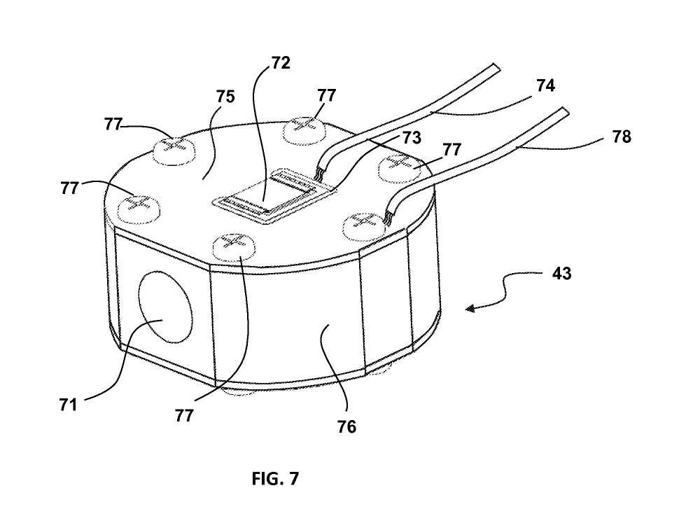

FIG. 7 shows additional detail of solar receiver 43. Solar receiver 43 has two openings allowing fluid transported by transport pipes 14 to flow through solar receiver 43. Inlet 71 is show in FIG. 7.

A receiver interface plate 75 is attached to receiver body 76 by fasteners 77, which, for example, may be screws, bolts, clamps, rivets or some other type of fastener.

A CPV cell 72 is placed on receiver interface plate 75 and partially surrounded by a cathode interface plate 73. Electricity generated by CPV cell 72 passes through a wire 74 attached to cathode interface plate 73 and through a wire 78 connected to receiver interface plate 75.

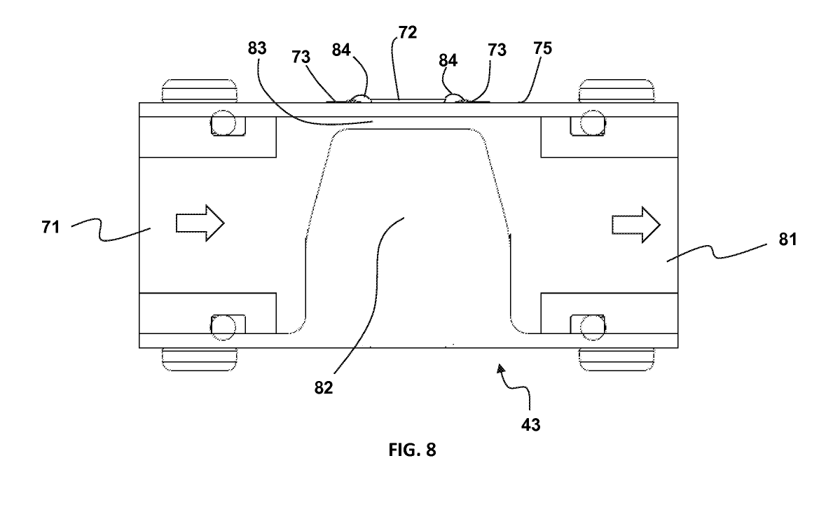

FIG. 8 is a cross-sectional view of solar receiver 43. Both inlet 71 and an outlet 81 are shown. Lead wires 84 are shown which electrically connect CPV cell 72 to the cathode interface plate 73. CPV cell 72 is bonded to receiver interface plate 75 with an electrically conductive adhesive or other conductive bonding material.

Receiver interface plate 75 functions as an anode interface for CPV cell 72 and as a thermal conductor to conduct heat from CPV cell 72 to fluid flowing in a passage 83 between inlet 71 and outlet 81. A peninsula 82 within solar receiver 43 results in passage 83 being narrowed. The size of peninsula 82 is selected so that heat is efficiently transferred to the liquid with a minimum of pressure drop. For example, fluid flow through solar receiver 43 is selected so that operating temperatures of solar receiver 43 are below 100 degrees Celsius.

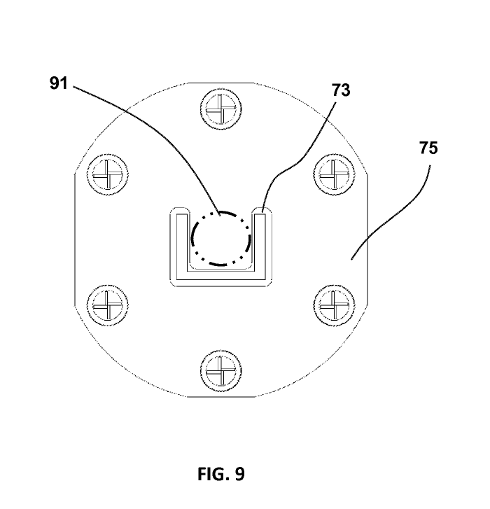

FIG. 9 is a top view of receiver interface plate 75 with CPV cell 72 removed. An area 91 demarks a focal area of concentrated sunlight reflected from reflector 41 shown in FIG. 5.

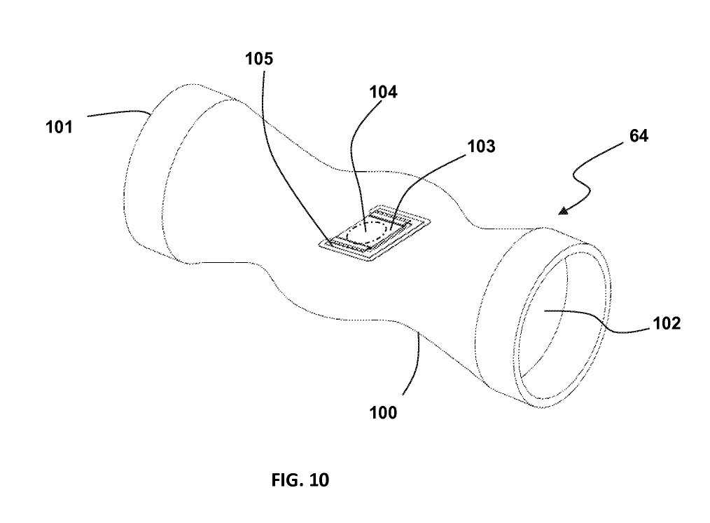

FIG. 10 shows additional detail of solar receiver 64. Solar receiver 64 has two openings allowing fluid transported by transport pipes 14 to flow through solar receiver 64. Inlet 101 and outlet 102 are show in FIG. 10.

A CPV cell 103 is placed on solar receiver 64 and partially surrounded by a cathode interface plate 105. Electricity generated by CPV cell 103 passes through a wire attached to cathode interface plate 105 and through a wire 78 connected to a body 100 of solar receiver 64. An area 104 demarks a focal area of concentrated sunlight reflected from reflector 41 shown in FIG. 6.

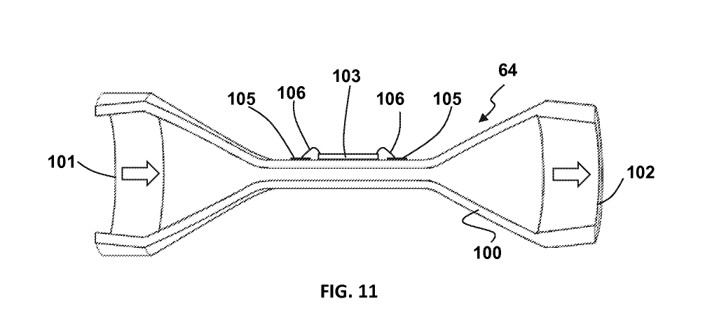

FIG. 11 is a cross-sectional view of solar receiver 64. Lead wires 106 are shown which electrically connect CPV cell 103 to the cathode interface plate 105. CPV cell 103 is bonded to body 100 of solar receiver 64 with an electrically conductive adhesive or other conductive bonding material.

Body 100 of solar receiver 64 functions as an anode interface for CPV cell 103 and as a thermal conductor to conduct heat from CPV cell 103 to fluid flowing in a passage 107 between inlet 101 and outlet 102. For example, body 100 is a copper pipe, or some other type of pipe, which has been squeezed so that passage 107 is narrowed. Fluid flow through 107 is selected so that heat is efficiently transferred to the liquid with a minimum of pressure drop. For example, fluid flow through solar receiver 64 is selected so that operating temperatures of solar receiver 64 are below 100 degrees Celsius when the fluid is water.

Solar receiver 64 provides a relatively inexpensive way to heat water while at the same time generating electricity vial CPV cell 103. Water running through copper pipes is heated by heat generated when running through narrowed passages near the location of a CPV cell. Concentrated light at the location of the CPV cell results in electrical current produced by the CPV cell and thermal energy being transferred to the water flowing through the narrowed passages.

The foregoing discussion discloses and describes merely exemplary methods and implementations. As will be understood by those familiar with the art, the disclosed subject matter may be embodied in other specific forms without departing from the spirit or characteristics thereof. Accordingly, the present disclosure is intended to be illustrative, but not limiting, of the scope of the invention, which is set forth in the following claims.

We claim:

1. Solar receiver comprising:
a fluid inlet;
a fluid outlet;
a narrowed passage between the fluid inlet and the fluid outlet; and,
a concentrated photovoltaic receiver mounted on a region close to the narrowed passage so that the thermal energy from the region is conducted to fluid as the fluid traverses the narrowed passage, the photovoltaic receiver generating electrical current from concentrated sunlight.

2. A solar receiver as in claim 1 wherein the concentrated photovoltaic receiver is mounted on a receiver interface plate located above a peninsula within the solar receiver that borders and forms the narrowed passage.

3. A solar receiver as in claim 1 wherein a peninsula within the solar receiver borders and forms the narrowed passage.

4. A solar receiver as in claim 1 wherein a body of the solar receiver is formed by a pipe, the pipe being partially flattened to form the narrowed passage.

5. A solar receiver as in claim 1 wherein a body of the solar receiver is formed by a pipe, the pipe being partially flattened to form the narrowed passage the concentrated photovoltaic receiver being mounted on the pipe where the pipe is partially flattened.

6. A solar receiver as in claim 1 wherein a body of the solar receiver is formed by a copper pipe, the copper pipe being partially flattened to form the narrowed passage.

7. A solar receiver as in claim 1 wherein a body of the solar receiver is formed by a copper pipe, the copper pipe being partially flattened to form the narrowed passage the concentrated photovoltaic receiver being mounted on the copper pipe where the copper pipe is partially flattened.

8. A concentrating heat and electricity system, each concentrating heat and electricity system comprising:
a frame; and,
a plurality of receiver modules mounted on the frame, each receiver module comprising,
a plurality of solar receivers, each receiver module including:
a fluid inlet,
a fluid outlet,
a narrowed passage between the fluid inlet and the fluid outlet, and
a concentrated photovoltaic receiver mounted on a region close to the narrowed passage so that the thermal energy from the region is conducted to fluid as the fluid traverses the narrowed passage, the photovoltaic receiver generating electrical current from concentrated sunlight.

9. A concentrating heat and electricity system as in claim 8 additionally comprising a base structure on which the frame is mounted, wherein each of the plurality of receiver modules is separated from other of the plurality of receiver modules so that wind flow between the receiver modules reduces wind load on the base structure.

10. A concentrating heat and electricity system as 8 in wherein each concentrated photovoltaic receiver is mounted on a receiver interface plate located above a peninsula that forms a narrowed passage.

11. A concentrating heat and electricity system as in claim 8 wherein within each solar receiver a peninsula borders and forms the narrowed passage.

12. A concentrating heat and electricity system as in claim 8 wherein a body of each solar receiver is formed by a pipe which is partially flattened to form a narrowed passage.

13. A concentrating heat and electricity system as in claim 8 wherein a body of each solar receiver is formed by a pipe which is partially flattened to form the narrowed passage, the concentrated photovoltaic receiver for each solar receiver being mounted on the pipe where the pipe is partially flattened.

14. A concentrating heat and electricity system as in claim 8 wherein for each solar receiver, a reflector is arranged to reflect concentrated sunlight toward the solar receiver.

15. A concentrating heat and electricity system as in claim 8 wherein for each solar receiver a plastic reflector having a reflective surface is arranged to reflect concentrated sunlight toward the solar receiver.

16. A concentrating heat and electricity system as in claim 8 additionally comprising transport pipes that transport fluid to the plurality of receiver modules.

17. A concentrating heat and electricity system as in claim 8 wherein the fluid is water.

18. A method for providing generating electricity and heating fluid comprising:
exposing a concentrated photovoltaic receiver to concentrated sunlight so that the concentrated photovoltaic receiver generates electricity, the concentrated photovoltaic receiver being mounted on a solar receiver; and,
passing the fluid through a narrowed region within the solar receiver the narrowed region being located adjacent to the concentrated photovoltaic receiver so that thermal energy is transferred from the concentrated sunlight to the fluid as the fluid passes through the narrowed region.

19. A method as in claim 18 wherein passing the fluid through the narrowed region includes passing the fluid through a partially flattened area of a pipe, the concentrated photovoltaic receiver being mounted on the pipe where the pipe is partially flattened.

20. A method as in claim 18 wherein passing the fluid through the narrowed region includes passing the fluid around a peninsula within the solar receiver wherein the peninsula borders and forms the narrowed passage.
